(19) United States
(12) Patent Application Publication
(10) Pub. No.: US 2026/0334229 A1
(43) Pub. Date: Oct. 22, 2026

(54) THERMAL INTERFACE MATERIAL LAYER PROTECTION STRUCTURES AND METHODS OF FORMING THE SAME

(71) Applicant: Taiwan Semiconductor Manufacturing Company Limited, Hsinchu (TW)

(72) Inventor: Wei-Hung Lin, Hsinchu County (TW)

(21) Appl. No.: 19/722,889

(22) Filed: Jun. 28, 2026

Related U.S. Application Data
(62) Division of application No. 18/110,009, filed on Feb. 15, 2023.

(51) Int. Cl. H10W 40/70; H10W 42/00; H10W 72/00; H10W 74/01; H10W 74/10; H10W 90/00; H10W 90/20

(52) U.S. Cl. CPC H10W 40/70; H10W 42/121; H10W 74/016; H10W 74/117; H10W 90/00; H10W 90/701; H10W 72/877; H10W 90/288

(57) ABSTRACT

A semiconductor package includes an interposer module on a package substrate, a thermal interface material (TIM) layer on the interposer module, a TIM layer protection structure on a side surface of the TIM layer and a side surface of the interposer module, and a package lid on the interposer module, the TIM layer and the TIM layer protection structure. A method of forming the semiconductor package may include mounting an interposer module on a package substrate, locating a thermal interface material layer on the interposer module, locating a package lid on the interposer module and the TIM layer, and forming a TIM layer protection structure on a side surface of the TIM layer and a side surface of the interposer module, through a filling hole in the package lid.

### RELATED APPLICATIONS

This application is a divisional of U.S. patent application Ser. No. 18/110,009 entitled “Thermal Interface Material Layer Protection Structures and Methods of Forming the Same,” filed Feb. 15, 2023, the entire contents of which are hereby incorporated by reference for all purposes.

### BACKGROUND

A semiconductor package may include one or more semiconductor dies that may be stacked or mounted on an interposer. During operation, the semiconductor dies may generate a large amount of heat. For improved performance, the generated heat may be dissipated.

The semiconductor package may include a thermal interface material (TIM) layer to help dissipate heat. In particular, the TIM layer may help to transport heat from the interposer (e.g., from a semiconductor chip on the interposer) to a package lid of the semiconductor package. The TIM layer may be of particular benefit in large semiconductor packages and advanced semiconductor packages.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a vertical cross-sectional view of the semiconductor package according to one or more embodiments.

FIG. 1B illustrates a magnified vertical cross-sectional view of the filling hole in the package lid according to one or more embodiments.

FIG. 1C illustrates a magnified vertical cross-sectional view of the degassing hole in the package lid according to one or more embodiments.

FIG. 1D illustrates a plan view of the package lid illustrated in FIG. 1A according to one or more embodiments.

FIG. 2A is a vertical cross-sectional view of an intermediate structure including the package substrate upper bonding pads and the package substrate lower bonding pads, according to one or more embodiments.

FIG. 2B is a vertical cross-sectional view of an intermediate structure including the package substrate upper surface layer and package substrate lower surface layer, according to one or more embodiments.

FIG. 2C is a vertical cross-sectional view of an intermediate structure including openings in the package substrate upper surface layer and openings in package substrate lower surface layer, according to one or more embodiments.

FIG. 2D illustrates a vertical cross-sectional view of an intermediate structure in which the interposer module may be mounted on the package substrate (e.g., via a flip chip bonding (FCB) process) according to one or more embodiments.

FIG. 2E illustrates a vertical cross-sectional view of an intermediate structure in which the package underfill layer may be formed on the package substrate according to one or more embodiments.

FIG. 2F illustrates a vertical cross-sectional view of an intermediate structure in which the TIM layer may be attached to the upper surface of the interposer module according to one or more embodiments.

FIG. 2G illustrates a vertical cross-sectional view of an intermediate structure in which the adhesive may be applied to the package substrate according to one or more embodiments.

FIG. 2H illustrates a vertical cross-sectional view of an intermediate structure in which the stiffener ring may be attached to (e.g., mounted on) the package substrate according to one or more embodiments.

FIG. 2I illustrates a vertical cross-sectional view of an intermediate structure in which the package lid may be attached to the stiffener ring according to one or more embodiments.

FIG. 2J illustrates a vertical cross-sectional view of an intermediate structure in which the TIM layer protection structure may be added to the semiconductor package according to one or more embodiments.

FIG. 2K illustrates a plan view of an intermediate structure including the TIM layer protection structure on the package substrate according to one or more embodiments.

FIG. 2L illustrates a vertical cross-sectional view of an intermediate structure including the filling plug and the degassing plug according to one or more embodiments.

FIG. 2M illustrates a vertical cross-sectional view of an intermediate structure in which a plurality of solder balls may be formed on the package substrate according to one or more embodiments.

FIG. 3 is a flow chart illustrating a method of forming a semiconductor package according to one or more embodiments.

FIG. 4A illustrates a plan view of a first alternative design of the package lid according to one or more embodiments.

FIG. 4B illustrates a plan view of a second alternative design of the package lid according to one or more embodiments.

FIG. 4C illustrates a plan view of a third alternative design of the package lid according to one or more embodiments.

FIG. 5 illustrates a vertical cross-sectional view of a fourth alternative design of the package lid according to one or more embodiments.

FIG. 6 illustrates a vertical cross-sectional view of a fifth alternative design of the package lid according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

A thermal variation (e.g., heating, cooling) may cause a typical semiconductor package to warp (e.g., thermal stress induced warp bending). This package warpage may induce delamination of the TIM layer from the interposer module, which may result in a failure of the semiconductor package. In such instances of package warpage, the TIM layer may delaminate from an upper surface of the interposer module at a corner of the interposer module.

One or more embodiments of the present disclosure may include a TIM layer protection structure. The TIM layer protection structure may help to protect the TIM layer—to inhibit (e.g., prevent) the TIM layer from delaminating off of the interposer module. The TIM layer protection structure may, therefore, provide improved reliability and better thermal dissipation performance for the overall semiconductor package. The TIM layer protection structure may be located in an air gap surrounding an interposer module (e.g., a semiconductor die/chip, integrated fan-out chiplets, integrated multiple logic chiplets, etc.) and between a package lid and package substrate (e.g., integrated circuit (IC) substrate).

In one or more embodiments, the TIM layer protection structure may be added to the semiconductor package after the package lid is attached to the package substrate over the interposer module. In one or more embodiments, the package lid may include a filling hole and a degassing hole. A TIM layer protection structure material (e.g., a liquid material) may be injected into the filling hole while a gas (e.g., air, nitrogen, etc.) may exit the semiconductor package through the degassing hole.

The TIM layer protection structure material may include, for example, a material such as or similar to an underfill material. The TIM layer protection structure may have a coefficient of thermal expansion (CTE) between 3 ppm/°C and 20 ppm/°C. The TIM layer protection structure may have thermal conductivity that is greater than 1 W/m·K.

The TIM layer protection structure material may cure to form a solid TIM layer protection structure. The TIM layer protection structure may form a strong bond between the package lid, the package substrate and the interposer module (e.g., which may include a semiconductor die/chip). The TIM layer protection structure may be formed underneath the package lid, above the package substrate and surrounding the interposer module.

A ratio of a thickness of the TIM layer protection structure to a thickness of the interposer module (e.g., chip thickness) may be greater than 1.0 and less than 3.0. Further, the package lid may have a package lid length in a first direction and the TIM layer protection structure may have a TIM layer protection structure length in the first horizontal direction. A ratio of the TIM layer protection structure length to the package lid length may be in a range between 0.3 and 1.0. The package lid may also have a package lid width in a second horizontal direction perpendicular to the first horizontal direction and the TIM layer protection structure may have a TIM layer protection structure width in the second horizontal direction. A ratio of the TIM layer protection structure width to the package lid width may be in a range between 0.3 and 1.0.

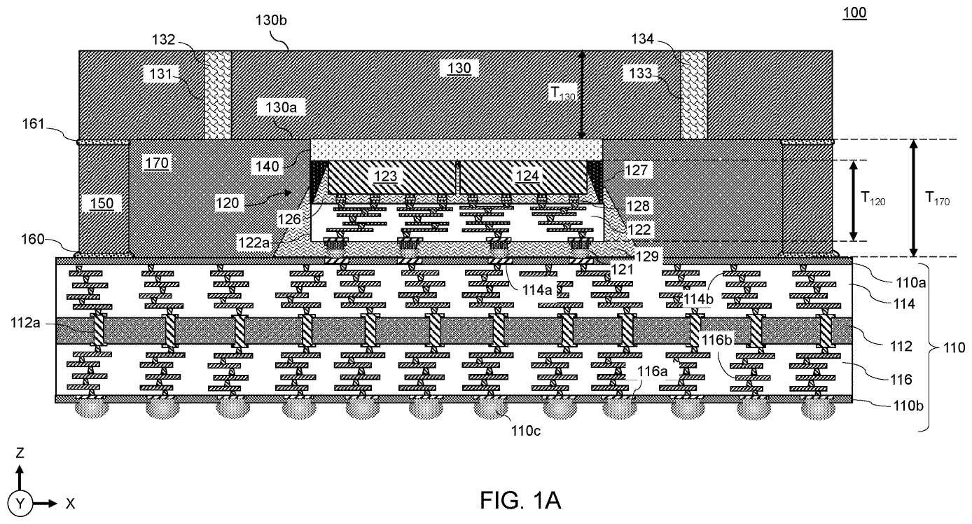

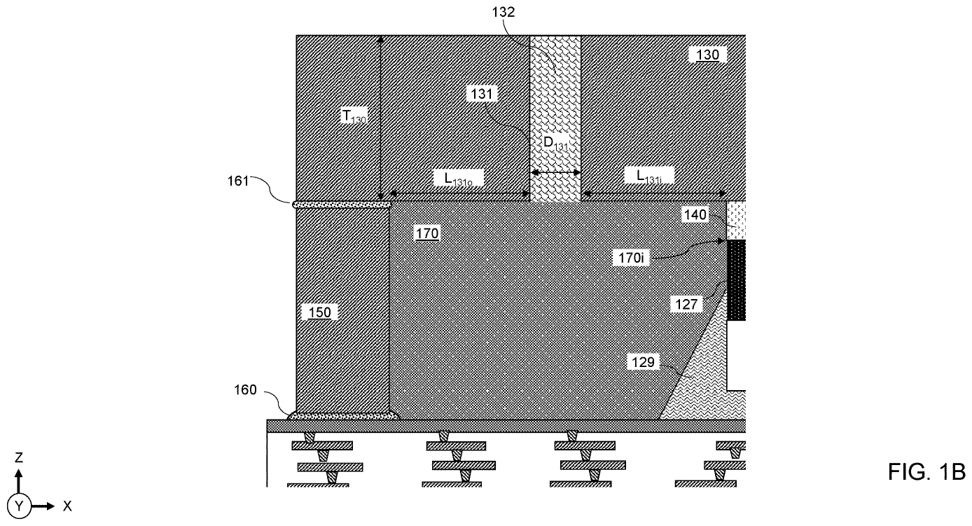

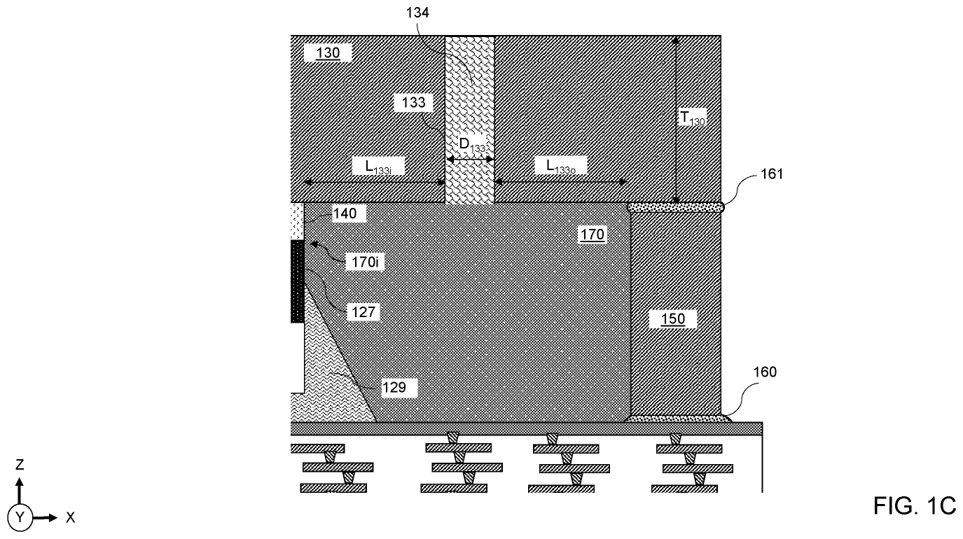

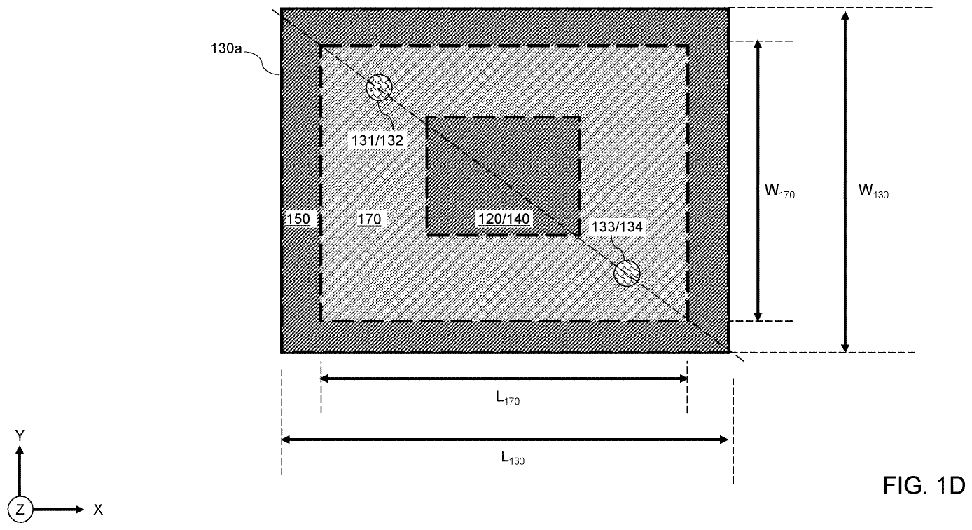

FIGS. 1A-1D provide different views of a semiconductor package 100 (e.g., organic/silicon interposer package) according to one or more embodiments. FIG. 1A illustrates a vertical cross-sectional view of the semiconductor package 100 according to one or more embodiments. FIG. 1B illustrates a magnified vertical cross-sectional view of the filling hole 131 in the package lid 130 according to one or more embodiments. FIG. 1C illustrates a magnified vertical cross-sectional view of the degassing hole 133 in the package lid 130 according to one or more embodiments. FIG. 1D illustrates a plan view of the package lid 130 according to one or more embodiments.

The semiconductor package 100 may include a package substrate 110, an interposer module 120 mounted on the package substrate 110, and a package lid 130 on the interposer module 120 and attached to the package substrate 110. The semiconductor package 100 may also include a TIM layer 140 on the interposer module 120. The semiconductor package 100 may also include a TIM layer protection structure 170 that may protect that TIM layer 140. In particular, the TIM layer protection structure 170 may inhibit or mitigate against a delamination of the TIM layer 140 from a surface of the interposer module 120.

The package substrate 110 may include, for example, a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). In particular, the package substrate 110 may include a build-up film substrate such as an Ajinomoto build-up film (ABF) substrate. That is, in at least one embodiment, each of the package substrate upper dielectric layer 114 and the package substrate lower dielectric layer 116 may be described as an ABF layer.

The core 112 may provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclo-butene (BCB), or polybenzobisoxazole (PBO). Other suitable dielectric materials are within the contemplated scope of disclosure.

The core 112 may include one or more through vias 112a. The one or more through vias 112a may extend from a lower surface of the core 112 to an upper surface of the core 112. The one or more through vias 112a may allow an electrical connection between the package substrate upper dielectric layer 114 and the package substrate lower dielectric layer 116. The one or more through vias 112a may include, for example, one or more layers and may include metals, metal alloys, and/or or other metal-containing compounds (e.g., Cu, Al, Mo, Co, Ru, W, TiN, TaN, WN, etc.). Other suitable metal materials are within the contemplated scope of disclosure.

The package substrate lower dielectric layer 116 may include a plurality of layers and, in particular, may include a build-up film (e.g., ABF). The package substrate lower dielectric layer 116 may include an organic material such as a polymer material. In particular, the package substrate lower dielectric layer 116 may include one or more layers of dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. In particular, the package substrate lower bonding pads 116a may be exposed on the board-side surface of the package substrate lower dielectric layer 116. The package substrate lower dielectric layer 116 may also include one or more metal interconnect structures 116b. The metal interconnect structures 116b may be connected to the package substrate lower bonding pads 116a and the through vias 112a in the core 112. The metal interconnect structures 116b may include metal layers (e.g., copper traces) and metal vias connecting the metal layers. The package substrate lower bonding pads 116a and the metal interconnect structures 116b may include, for example, one or more layers and may include metals, metal alloys, and/or or other metal-containing compounds (e.g., Cu, Al, Mo, Co, Ru, W, TiN, TaN, WN, etc.). Other suitable metal materials for use in the metal interconnect structures 116b are within the contemplated scope of disclosure.

A package substrate lower surface layer 110b may be formed on the board-side surface of the package substrate lower dielectric layer 116. The package substrate lower surface layer 110b may partially cover the package substrate lower bonding pads 116a. The package substrate lower surface layer 110b may include one or more of a passivation layer and protection layer. The package substrate lower surface layer 110b may include, for example, a dielectric polymer material such as polyimide (PI), benzocyclobutene (BCB), or polybenzobisoxazole (PBO). The package substrate lower surface layer 110b may alternatively or additionally include silicon oxide, silicon nitride, low-k dielectric materials such as carbon-doped oxides, extremely low-k dielectric materials such as porous carbon doped silicon dioxide, or a combination thereof. Other suitable dielectric materials are within the contemplated scope of disclosure.

A ball-grid array (BGA) including a plurality of solder balls 110c may be formed on the board-side surface of the package substrate lower dielectric layer 116. The solder balls 110c may allow the semiconductor package 100 to be securely mounted on a substrate such as a printed circuit board (PCB) and electrically coupled to the PCB substrate. The solder balls 110c may contact the package substrate lower bonding pads 116a, respectively.

The package substrate upper dielectric layer 114 may be formed on an upper surface of the core 112. The package substrate upper dielectric layer 114 may also include a plurality of layers and, in particular, may include a build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may include one or more package substrate upper bonding pads 114a on a chip-side surface of the package substrate upper dielectric layer 114. In particular, the package substrate upper bonding pads 114a may be exposed on the chip-side surface of the package substrate upper dielectric layer 114. In at least one embodiment, a bonding pad surface layer (not shown) (e.g., one or more layers of metals (e.g., tin, nickel, palladium, gold, etc.) and/or other materials) may be formed on the package substrate upper bonding pads 114a to improve solder joint reliability.

The package substrate upper dielectric layer 114 may also include one or more metal interconnect structures 114b. The metal interconnect structures 114b may include metal layers (e.g., copper traces) and metal vias connecting the metal layers. The package substrate upper bonding pads 114a may be electrically connected to the solder balls 110c of the BGA by way of the metal interconnect structures 114b, the through vias 112a, the metal interconnect structures 116b, and the package substrate lower bonding pads 116a. The package substrate upper bonding pads 114a and the metal interconnect structures 114b may include, for example, one or more layers and may include metals, metal alloys, and/or or other metal-containing compounds (e.g., Cu, Al, Mo, Co, Ru, W, TiN, TaN, WN, etc.). Other suitable metal materials are within the contemplated scope of disclosure.

A package substrate upper surface layer 110a may be formed on the chip-side surface of the package substrate upper dielectric layer 114. The package substrate upper surface layer 110a may including a coating layer, laminate layer, etc. The package substrate upper surface layer 110a may be formed so as to at least partially cover the package substrate upper bonding pads 114a.

In at least one embodiment, the package substrate upper surface layer 110a may include a solder resist layer (e.g., solder mask layer). The solder resist layer may include a thin layer of polymer material (e.g., epoxy polymer). The solder resist layer may have a thickness in a range from about 5 μm to 50 μm. In at least one embodiment, the solder resist layer may have a thickness in a range from about 10 μm to 30 μm. Greater or lesser thickness of the solder resist layer may be used. The solder resist layer may be formed so as to cover the package substrate upper bonding pads 114a and other metal features (e.g., conductive lines, copper traces) on the chip-side surface of the package substrate 110. The solder resist layer may protect the package substrate upper bonding pads 114a and other metal features from oxidation. The solder resist layer may also inhibit (e.g., prevent) solder bridges (e.g., unintended electrical connections) from forming between closely spaced metal features. The solder resist layer may include solder resist openings (SROs) over the package substrate upper bonding pads 114a, respectively. An upper surface of the package substrate upper bonding pads 114a may be exposed through the SROs. The SROs may have a tapered sidewall so that a diameter of the SRO (in the X-Y plane) may decrease in a direction toward the package substrate upper bonding pad 114a.

The package substrate upper surface layer 110a may alternatively or additionally include a layer other than a solder resist layer, such as a passivation layer or protection layer. In particular, the package substrate upper surface layer 110a may alternatively or additionally include a dielectric polymer material such as polyimide (PI), benzocyclo-butene (BCB), or polybenzobisoxazole (PBO), silicon oxide, silicon nitride, low-k dielectric materials such as carbon-doped oxides, extremely low-k dielectric materials such as porous carbon doped silicon dioxide, a combination thereof or other suitable material. The package substrate upper surface layer 110a may alternatively or additionally be formed, for example, by chemical vapor deposition (CVD), physical vapor deposition (PVD), spin coating, lamination or other suitable deposition technique.

The interposer module 120 may be mounted by controlled collapse chip connection (C4) bumps 121 on the package substrate upper bonding pads 114a in the package substrate 110. The interposer module 120 may include an interposer dielectric layer 122 that may include metal interconnects 122a electrically connected to the C4 bumps 121. The interposer module 120 may also include a first semiconductor die 123 and second semiconductor die 124 that may each be mounted on the interposer dielectric layer 122. It should be noted that any number of semiconductor dies may be mounted on the interposer dielectric layer 122.

The first semiconductor die 123 and second semiconductor die 124 may be mounted on the interposer dielectric layer 122 by micro-bumps 128 that may be electrically connected to the metal interconnects 122a. A package underfill layer 129 may be formed under and around the interposer module 120 and the C4 bumps 121 so as to fix the interposer module 120 to the package substrate 110. The package underfill layer 129 may be formed of an epoxy-based polymeric material.

Each of the first semiconductor die 123 and second semiconductor die 124 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., dynamic random access memory (DRAM) die, a Wide I/O die, a M-RAM die, a R-RAM die, a NAND die, static random access memory (SRAM), etc. ), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a memory cube (e.g., HBM, HMC, etc.), a high data rate transceiver die, a I/O interface die, a IPD die (e.g., integrated passives device), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc.

Each of the first semiconductor die 123 and second semiconductor die 124 may include, for example, an active region (not shown). The active region may include a front end of line (FEOL) region including electronic circuitry including various electronic devices (e.g., transistors, resistors, etc.). In particular, the FEOL region may include one or more logic circuits including logic devices (e.g., logic gates) and/or one or more memory circuits including memory devices (e.g., volatile memory (VM) devices and/or non-volatile memory (NVM) devices). The active region may also include a back end of line (BEOL) region that may include interlayer dielectric having a plurality of dielectric layers. The dielectric layers may include, for example, SiO₂, a dielectric polymer or other suitable dielectric material. The interlayer dielectric may include one or more metal interconnect structures formed therein. The metal interconnect structures may include metal traces and metal vias formed in the dielectric layers and provide an electrical connection to the electronic circuitry in the FEOL region.

An interposer underfill layer 126 may be formed around the micro-bumps 128 and between the first semiconductor die 123 and the interposer dielectric layer 122, as well as between the second semiconductor die 124 and the interposer dielectric layer 122. The interposer underfill layer 126 may be formed continuously under both of the first semiconductor die 123 and second semiconductor die 124, as illustrated in FIG. 1A. Alternatively, the interposer underfill layer 126 may be formed as separate portions under each of the first semiconductor die 123 and second semiconductor die 124. The interposer underfill layer 126 may also be formed between first semiconductor die 123 and the second semiconductor die 124. The interposer underfill layer 126 may also be formed of an epoxy-based polymeric material.

A molding material layer 127 may be formed over the first semiconductor die 123, second semiconductor die 124, the interposer underfill layer 126 and the interposer dielectric layer 122. The molding material layer 127 may be formed of an epoxy molding compound (EMC).

The TIM layer 140 may include, for example, a gel TIM, graphite TIM, metal TIM, solder TIM and a carbon nanotube TIM. Other types of TIMs are within the contemplated scope of this disclosure. In at least one embodiment, the TIM layer 140 may be in a range from 30 μm to 150 μm. The TIM layer 140 may be formed on the interposer module 120 to dissipate of heat generated during operation of the semiconductor package 100 (e.g., operation of first semiconductor die 123 and second semiconductor die 124. The TIM layer 140 may be attached to the interposer module 120, for example, by a thermally conductive adhesive. In particular, the TIM layer 140 may contact an upper surface of first semiconductor die 123, an upper surface of second semiconductor die 124, an upper surface of the molding material layer 127 and/or an upper surface of the interposer underfill layer 126. The TIM layer 140 may have a low bulk thermal impedance and high thermal conductivity. The bond-line-thickness (BLT) (e.g., a distance between the package lid 130 and the interposer module 120) may be less than about 100 μm, although greater or lesser distances may be used.

The semiconductor package 100 may also include a stiffener ring 150 that may be fixed to the package substrate 110 by an adhesive 160 such as a silicone adhesive or an epoxy adhesive. Other adhesives are within the contemplated scope of this disclosure. The stiffener ring 150 may be formed of a metal such as copper with a nickel coating, or an aluminum alloy. The stiffener ring 150 may alternatively be formed of a ceramic material or hard plastic (polymer) material. The stiffener ring 150 may be formed on the package substrate 110 so as to surround (e.g., encircle) the interposer module 120 in the x-y plane. The stiffener ring 150 may extend in a substantially perpendicular direction (e.g., in the z-direction) from the package substrate 110. The stiffener ring 150 may help to provide rigidity to the package substrate 110 and interposer module 120.

The package lid 130 may be connected to the stiffener ring 150 so as to cover the interposer module 120. The package lid 130 may be fixed to the stiffener ring 150 by an adhesive 161 (e.g., a silicone adhesive or an epoxy adhesive). The package lid 130 may contact at least a portion of the TIM layer 140. In one or more embodiments, the package lid 130 may directly contact an entire upper surface of the TIM layer 140. The package lid 130 may be formed, for example, of metal, ceramic or polymer material. The package lid 130 may have a plate shape (e.g., planar shape) and be substantially parallel to an upper surface of the package substrate 110. The package lid 130 may extend, for example, in an x-y plane in FIG. 1A. The package lid 130 may include a central portion that is substantially aligned in the z-direction with a central portion of the interposer module 120.

The package lid 130 may include a bottom surface 130a and an upper surface 130b opposite the bottom surface 130a in the z-direction. The package lid 130 may have a thickness T₁₃₀. The bottom surface 130a of the package lid 130 may extend across the package lid 130 between opposing sides of the stiffener ring 150 and contact the TIM layer 140. The TIM layer 140 may be compressed between the bottom surface 130a of the package lid 130 and the upper surface of the interposer module 120. The bottom surface 130a of the package lid 130 may be fixed to the stiffener ring 150 by the adhesive 161. The bottom surface 130a may be substantially planar. In particular, a height (e.g., in the z-direction) of the bottom surface 130a from the package substrate upper surface layer 110a may be substantially uniform across an entirety of the bottom surface 130a. Alternatively, the package lid 130 may also include a bottom step region (not shown) that may project from the bottom surface 130a and contact the TIM layer 140. The bottom step region may extend in a substantially perpendicular direction from the bottom surface 130a. The bottom step region may be formed around the central region of the package lid 130.

The semiconductor package 100 may also include a TIM layer protection structure 170. The TIM layer protection structure 170 may help to protect the TIM layer 140 and, in particular, may help to inhibit (e.g., prevent) the TIM layer 140 from delaminating off of the interposer module 120. The TIM layer protection structure 170 may, therefore, provide improved reliability and better thermal dissipation performance of the semiconductor package 100.

The TIM layer protection structure 170 may include a material that is substantially similar to the package underfill layer 129 and/or the interposer underfill layer 126. In at least one embodiment, the TIM layer protection structure 170 may include a polymeric material and in particular, an epoxy-based polymeric material. In at least one embodiment, the TIM layer protection structure 170 may include an added material (e.g., filler material) for improving a property of the TIM layer protection structure 170 (e.g., thermal conductivity, CTE, etc.). The added material may include, for example, metal powder, metal oxide powder, etc. Other materials in the TIM layer protection structure 170 are within the contemplated scope of the disclosure.

The TIM layer protection structure 170 may be located in a space (e.g., air gap) surrounding an interposer module 120, between the interposer module 120 and the stiffener ring 150 and between the package lid 130 and package substrate 110. In at least one embodiment, the TIM layer protection structure 170 may substantially fill the space (e.g., air gap) surrounding an interposer module 120.

In at least one embodiment, the TIM layer protection structure 170 may have a coefficient of thermal expansion (CTE) between 3 ppm/°C and 20 ppm/°C. In at least one embodiment, the TIM layer protection structure may have thermal conductivity that is greater than 1 W/m·K. In at least one embodiment, the TIM layer protection structure may have a CTE that is greater than a CTE of the TIM layer. In at least one embodiment, the TIM layer protection structure may have a thermal conductivity that is greater than a thermal conductivity of the TIM layer. In at least one embodiment, the TIM layer protection structure 170 may be formed of a curable material that may cure to form a hard, solid structure. A ratio of a thickness T₁₇₀ of the TIM layer protection structure 170 to a thickness T₁₂₀ of the interposer module 120 (e.g., chip thickness) may be greater than 1.0 and less than 3.0. The TIM layer protection structure 170 may form a strong bond between the package lid 130, the package substrate 110 and the interposer module 120. In at least one embodiment, the TIM layer protection structure 170 may be bonded to one or more of the bottom surface 130a of the package lid 130, an upper surface of the package substrate 110, an outer side surface (sidewall) of the TIM layer 140, an outer side surface (sidewall) of the interposer module 120, an inner side surface (sidewall) of the stiffener ring 150, the package underfill layer 129, the adhesive 160 and the adhesive 161.

In at least one embodiment, the TIM layer protection structure 170 may be added to the semiconductor package 100 through a filling hole 131 in the package lid 130. The package lid 130 may also include a degassing hole 133 to facilitate the adding of the TIM layer protection structure 170. The package lid 130 may also include a filling plug 132 and a degassing plug 134 for plugging the filling hole 131 and degassing hole 133, respectively. The filling plug 132 and degassing plug 134 may include a polymeric material and in particular, an epoxy-based polymeric material. Other materials are within the contemplated scope of the disclosure.

Referring to FIG. 1B, the filling hole 131 may have a diameter D₁₃₁ (e.g., width) in a range from 3 mm to 10 mm. The diameter D₁₃₁ may be substantially uniform over the height (in the z-direction) of the filling hole 131. In at least one embodiment, diameter D₁₃₁ may vary over the height (in the z-direction) of the filling hole 131. As illustrated in FIG. 1B, the filling hole 131 may extend in the z-direction substantially perpendicular to the package lid 130. Alternatively, the filling hole 131 may be slanted with respect to the package lid 130.

The filling hole 131 may be located in a central region of the TIM layer protection structure 170. The filling hole 131 may be separated from the interposer module 120 by an inner length L₁₃₁ᵢ. The filling hole 131 may be separated from the stiffener ring 150 by an outer length L₁₃₁ₒ. In at least one embodiment, the filling hole 131 may be equidistant between the interposer module 120 and the stiffener ring 150 (e.g., L₁₃₁ᵢ=L₁₃₁ₒ).

The filling plug 132 may extend from the bottom surface 130a of the package lid 130 to the upper surface 130b of the package lid 130. An upper surface of the filling plug 132 may be substantially coplanar with the upper surface 130b of the package lid 130. A bottom surface of the filling plug 132 may be substantially coplanar with the bottom surface 130a of the package lid 130. Thus, a thickness of the filling plug 132 may be substantially the same as the thickness T₁₃₀ of the package lid 130. The filling plug 132 may fill an entirety of the filling hole 131 and completely seal the filling hole 131. The filling plug 132 may adhere and bond to a wall of the filling hole 131 over an entirety of the filling hole 131.

As further illustrated in FIG. 1B, the TIM layer protection structure 170 may include a TIM layer protection structure interface portion 170i. The TIM layer protection structure interface portion 170i may contact a side surface of the TIM layer 140 and a side surface of the molding material layer 127 (e.g., interposer module 120) at an interface between the TIM layer 140 and the molding material layer 127. The TIM layer protection structure interface portion 170i may extend continuously from the side surface of the TIM layer 140 to the side surface of the molding material layer 127 and thereby help to inhibit (e.g., prevent) a delamination of the TIM layer 140 from the molding material layer 127.

Referring to FIG. 1C, the degassing hole 133 may also have a diameter D₁₃₃ (e.g., width) in a range from 3 mm to 10 mm. The diameter D₁₃₃ may also be substantially uniform over the height (in the z-direction) of the degassing hole 133. In at least one embodiment, diameter D₁₃₃ may vary over the height (in the z-direction) of the degassing hole 133. In at least one embodiment, the diameter D₁₃₃ of the degassing hole 133 may be different than (e.g., less than) than the diameter D₁₃₁ of the filling hole 131. As illustrated in FIG. 1C, the degassing hole 133 may extend in the z-direction substantially perpendicular to the package lid 130. Alternatively, the degassing hole 133 may be slanted with respect to the package lid 130.

The degassing hole 133 may be located in a central region of the TIM layer protection structure 170. The degassing hole 133 may be separated from the interposer module 120 by an inner length L₁₃₃ᵢ. The degassing hole 133 may be separated from the stiffener ring 150 by an outer length L₁₃₃ₒ. In at least one embodiment, the degassing hole 133 may be equidistant between the interposer module 120 and the stiffener ring 150 (e.g., L₁₃₁ᵢ=L₁₃₁ₒ). In at least one embodiment, the inner length L₁₃₁ᵢ may be greater than the outer length L₁₃₃ₒ (e.g., L₁₃₁ᵢ>L₁₃₁ₒ). That is, the degassing hole 133 may be located in the package lid 130 closer to the stiffener ring 150 than the interposer module 120.

The degassing plug 134 may also extend from the bottom surface 130a of the package lid 130 to the upper surface 130b of the package lid 130. An upper surface of the degassing plug 134 may be substantially coplanar with the upper surface 130b of the package lid 130. A bottom surface of the degassing plug 134 may be substantially coplanar with the bottom surface 130a of the package lid 130. Thus, a thickness of the degassing plug 134 may be substantially the same as the thickness T₁₃₀ of the package lid 130. The degassing plug 134 may fill an entirety of the degassing hole 133 and completely seal the degassing hole 133. The degassing plug 134 may adhere and bond to a wall of the degassing hole 133 over an entirety of the degassing hole 133.

Referring to FIG. 1D, the package lid 130 is illustrated with a location of each of the stiffener ring 150, the interposer module 120 (and TIM layer 140) and the TIM layer protection structure 170 indicated by dashed lines. As illustrated in FIG. 1D, the package lid 130 may have a rectangular shape. Other shapes are within the contemplated scope of this disclosure.

In particular, the package lid 130 may have a length L₁₃₀ in the first horizontal direction(i.e., x-direction) and a width W₁₃₀ in a second horizontal direction (i.e., y-direction). The TIM layer protection structure 170 may be formed around an entire periphery of the interposer module 120 and TIM layer 140. The TIM layer protection structure 170 may have a length L₁₇₀ in the first horizontal direction (i.e., x-direction) and a width W₁₇₀ in the second horizontal direction (i.e., y-direction). A ratio R1 of the length L₁₇₀ of the TIM layer protection structure 170 to the length L₁₃₀ of the package lid 130 may be in a range between 0.3 and 1.0. A ratio R2 of the width W₁₇₀ of the TIM layer protection structure 170 to the width W₁₃₀ of the package lid 130 may be in a range between 0.3 and 1.0. The ratio R1 and the ratio R2 may be in the range between 0.3 and 1.0, to ensure that the TIM layer protection structure 170 provides sufficient bonding between the package lid 130, the package substrate 110 and the interposer module 120.

As illustrated in FIG. 1D, the filling hole 131 (and filling plug 132) and the degassing hole 133 (and degassing plug 134) may be substantially aligned with opposing corners of the package lid 130 and/or opposing corners of the interposer module 120. Other locations of the filling hole 131 (and filling plug 132) and degassing hole 133 (and degassing plug 134) are within the contemplated scope of disclosure. Each of the filling hole 131 and the degassing hole 133 may have a circular cross-sectional shape. Other shapes (e.g., oval shape, line shape, rectangular shape) are within the contemplated scope of disclosure. In at least one embodiment, the cross-sectional shape of the filling hole 131 (and filling plug 132) may be different than the cross-sectional shape of the degassing hole 133 (and degassing plug 134).

It should be noted that the diameter D₁₃₁ of the filling hole 131 and the diameter D₁₃₃ of the degassing hole 133 may depend on a thickness of the package lid 130. In at least one embodiment, the diameter D₁₃₁ and diameter D₁₃₃ may increase with an increasing thickness of the package lid 130. The diameter D₁₃₁ and diameter D₁₃₃ may also depend on a volume of the space to be filled by the TIM layer protection structure 170 (i.e., volume defined by the inner stiffener ring 150 and interposer 120, top surface of the package substrate 110 and bottom surface of the package lid 130). In at least one embodiment, the diameter D₁₃₁ and diameter D₁₃₃ may increase with an increasing volume of the space.

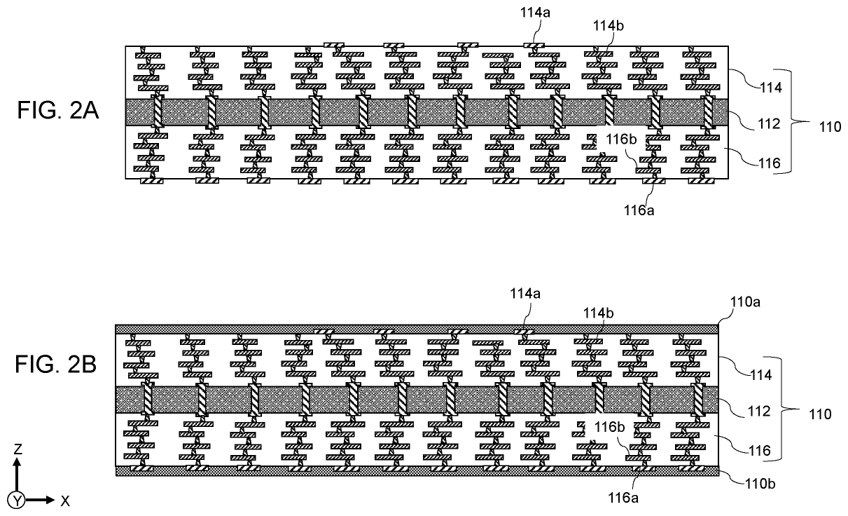

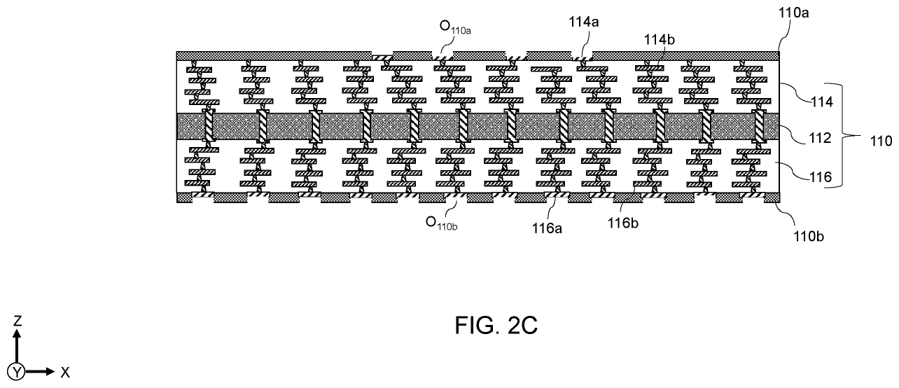

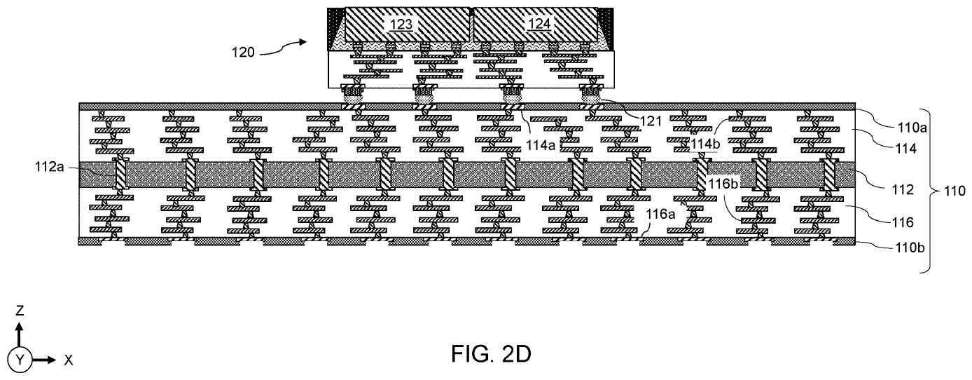

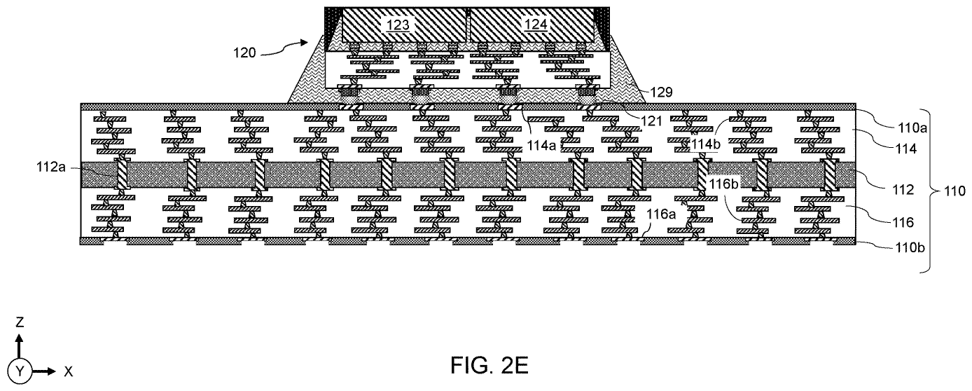

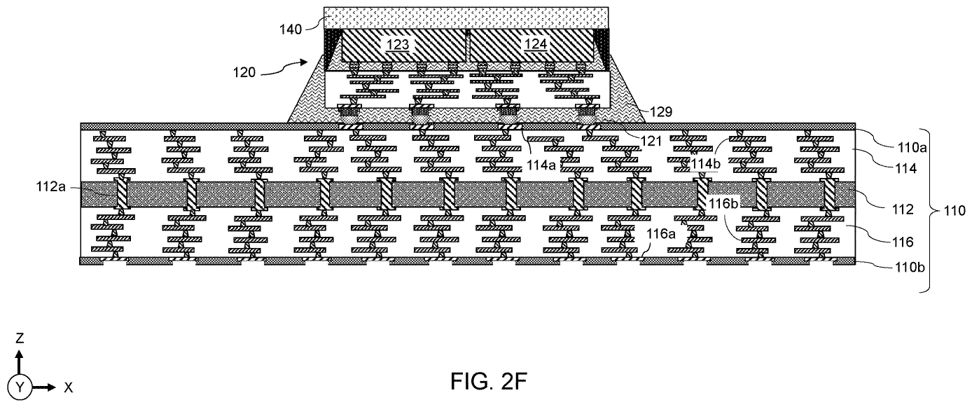

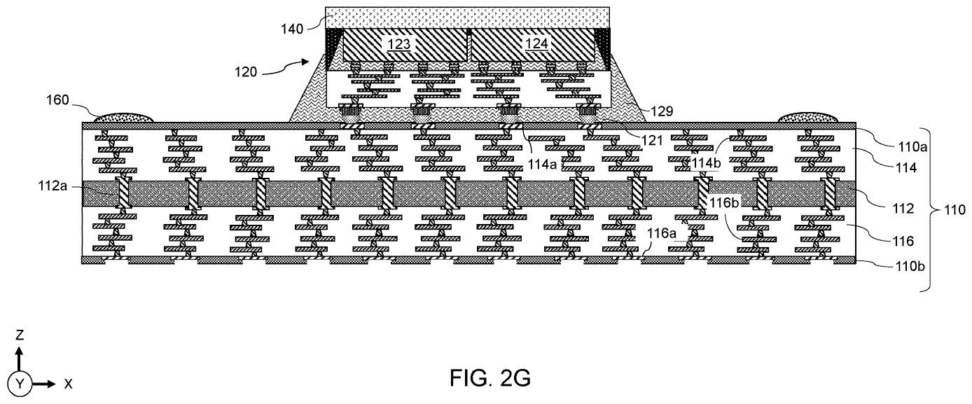

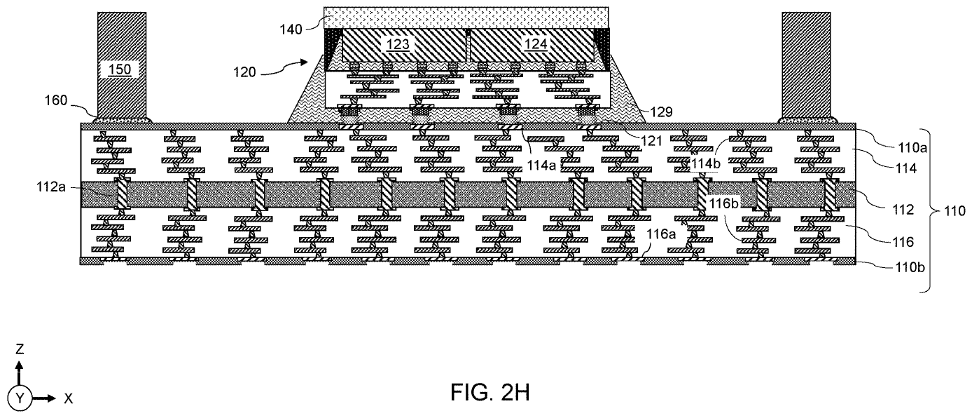

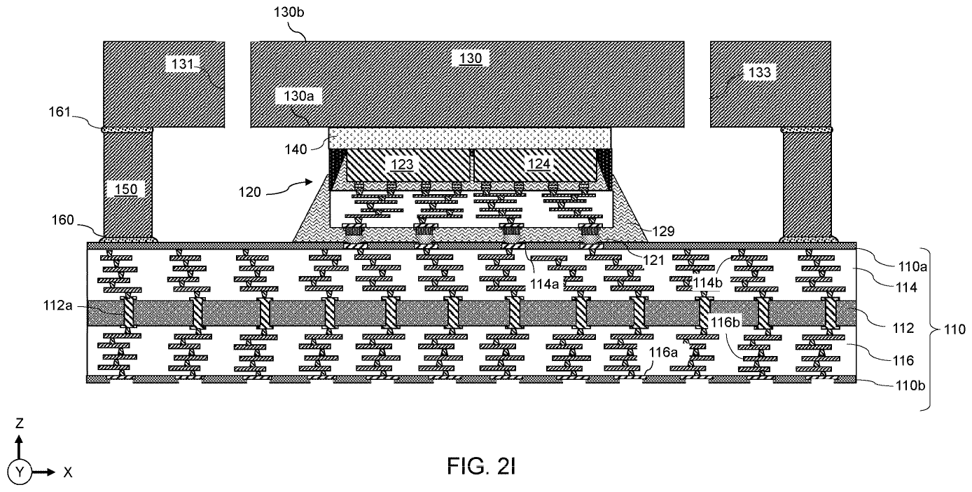

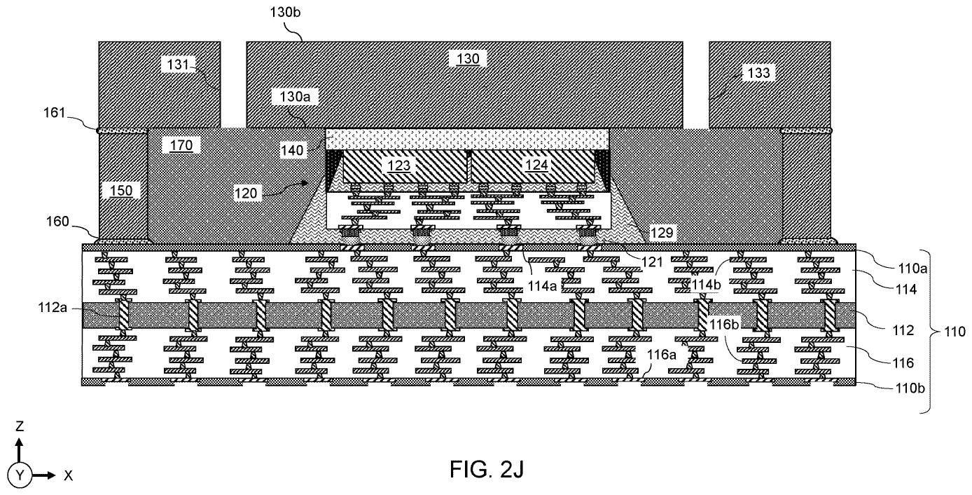

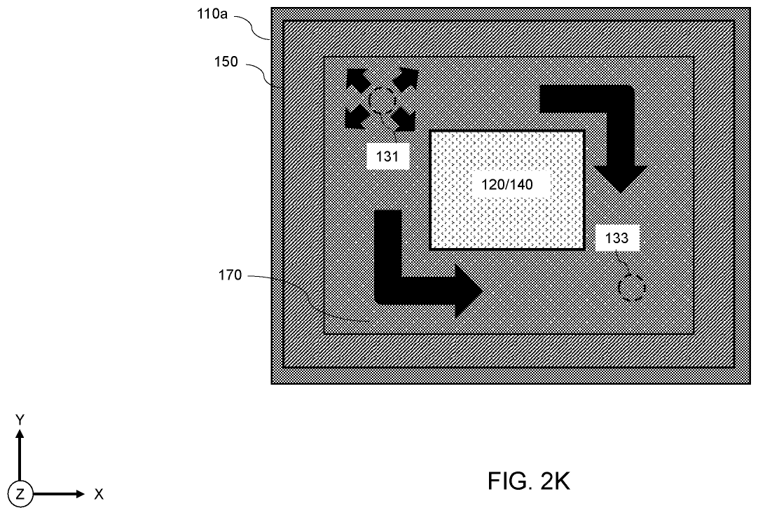

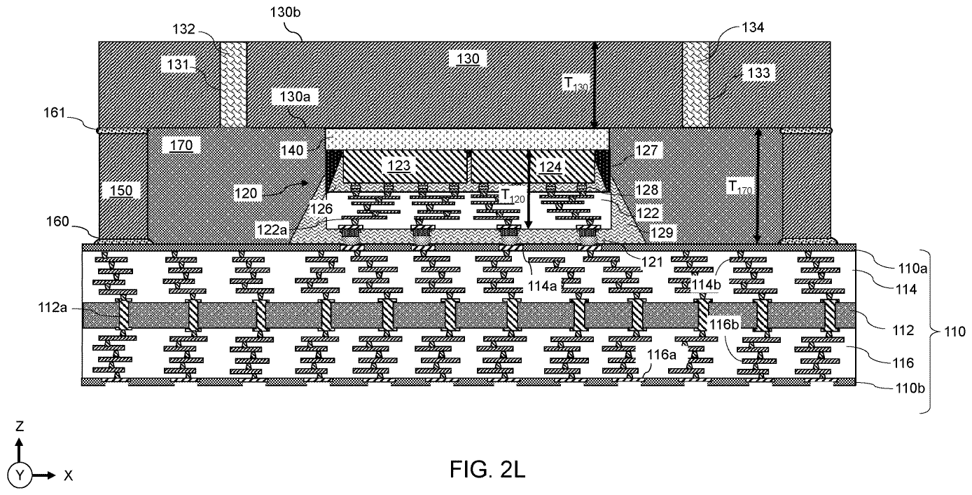

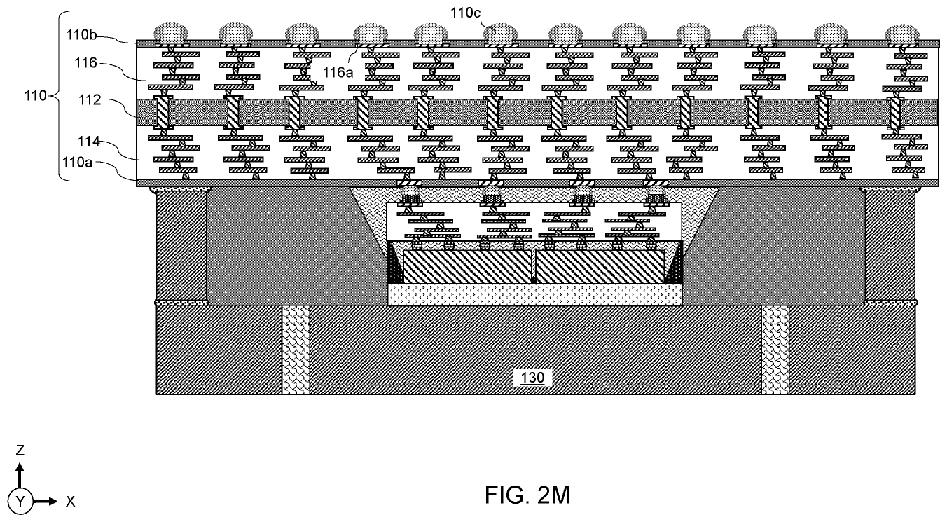

FIGS. 2A-2I illustrate a method of forming the semiconductor package 100 according to one or more embodiments. FIG. 2A is a vertical cross-sectional view of an intermediate structure including the package substrate upper bonding pads 114a and the package substrate lower bonding pads 116a, according to one or more embodiments. The package substrate upper bonding pads 114a may be formed, for example, on an uppermost dielectric layer of the package substrate upper dielectric layer 114. The package substrate upper bonding pads 114a may be formed so as to contact the metal interconnect structures 114b. The package substrate upper bonding pads 114a may be formed by depositing a metal layer (e.g., copper, aluminum or other suitable conductive materials) on the uppermost dielectric layer of the package substrate upper dielectric layer 114. The metal layer may then be patterned by etching (e.g., by wet etching, dry etching, etc.) so as to form the package substrate upper bonding pads 114a. Other suitable metal layer materials and etching processes may be within the contemplated scope of disclosure.

The package substrate lower bonding pads 116a may be formed, for example, on a lowest dielectric layer of the package substrate lower dielectric layer 116. The package substrate lower bonding pads 116a may be formed so as to contact the metal interconnect structures 116b. The package substrate lower bonding pads 116a may be formed by depositing a metal layer (e.g., copper, aluminum or other suitable conductive materials) on the lowest dielectric layer of the package substrate upper dielectric layer 114. The metal layer may then be patterned by etching (e.g., by wet etching, dry etching, etc.) so as to form the package substrate lower bonding pads 116a. Other suitable metal layer materials and etching processes may be within the contemplated scope of disclosure.

After formation, the package substrate upper bonding pads 114a and package substrate lower bonding pads 116a may optionally undergo a surface roughening treatment (e.g., copper surface roughening treatment which may also be referred to as copper zarazara (CZ) treatment). In the surface roughening treatment, a surface of the package substrate upper bonding pads 114a (e.g., a copper surface) and surface of the package substrate lower bonding pads 116a (e.g., a copper surface) may be etched by an organic acid-type microetching solution, to create a super-roughened surface (e.g., copper surface). The uniquely-roughened copper surface topography of the package substrate upper bonding pads 114a and package substrate lower bonding pads 116a may help to achieve a high copper-to-resin adhesion.

FIG. 2B is a vertical cross-sectional view of an intermediate structure including the package substrate upper surface layer 110a and package substrate lower surface layer 110b, according to one or more embodiments. In at least one embodiment, the package substrate upper surface layer 110a may include a solder resist layer (e.g., polymer material), also referred to as a solder mask. The package substrate upper surface layer 110a may also be referred to as the upper solder resist layer 110a, and the package substrate lower surface layer 110b may also be referred to as the lower solder resist layer 110b.

The package substrate upper surface layer 110a and package substrate lower surface layer 110b may be applied concurrently. The package substrate upper surface layer 110a and package substrate lower surface layer 110b may be applied, for example, as a liquid photo-imageable film. The liquid photo-imageable film can be applied, for example, by silk-screening or spraying the liquid photo-imageable film onto the surface of the package substrate 110. The liquid photo-imageable film may be applied over the package substrate upper bonding pads 114a and the package substrate lower bonding pads 116a. The package substrate upper surface layer 110a and package substrate lower surface layer 110b may alternatively be applied as a dry-film photo-imageable film that may be vacuum-laminated onto the surface of the package substrate 110 and over the package substrate upper bonding pads 114a and the package substrate lower bonding pads 116a, respectively.

The package substrate upper surface layer 110a and package substrate lower surface layer 110b may be applied so as to have a thickness that is slightly greater than a thickness of the package substrate upper bonding pads 114a and the package substrate lower bonding pads 116a, respectively. Alternatively, the package substrate upper surface layer 110a and package substrate lower surface layer 110b may be applied so as to have an upper surface that is substantially co-planar with an upper surface of the package substrate upper bonding pads 114a and the package substrate lower bonding pads 116a, respectively.

FIG. 2C is a vertical cross-sectional view of an intermediate structure including openings O₁₁₀ₐ in the package substrate upper surface layer 110a and openings O_{110b} in package substrate lower surface layer 110b, according to one or more embodiments.

Openings O₁₁₀ₐ may be formed in the package substrate upper surface layer 110a so as to expose an upper surface of the package substrate upper bonding pads 114a. Openings O_{110b} may be formed in the package substrate lower surface layer 110b so as to expose an upper surface of the package substrate lower bonding pads 116a. The openings O₁₁₀ₐ and the openings O_{110b} may be formed, for example, by using a photolithographic process. In at least one embodiment, the openings O₁₁₀ₐ and the openings O_{110b} may be formed in separate photolithographic processes.

The photolithographic process (e.g., processes) used to form the openings O₁₁₀ₐ may include forming a patterned photoresist mask (not shown) on the package substrate upper surface layer 110a, and etching (e.g., wet etching, dry etching, etc.) the exposed upper surface of the package substrate upper surface layer 110a through openings in the photoresist mask. The photoresist mask may be subsequently removed by ashing, dissolving the photoresist mask or by consuming the photoresist mask during the etch process.

The photolithographic process (e.g., processes) used to form the openings O_{110b} may include forming a patterned photoresist mask (not shown) on the package substrate lower surface layer 110b, and etching (e.g., wet etching, dry etching, etc.) the exposed upper surface of the package substrate lower surface layer 110b through openings in the photoresist mask. The photoresist mask may be subsequently removed by ashing, dissolving the photoresist mask or by consuming the photoresist mask during the etch process.

After the openings O₁₁₀ₐ are formed in the package substrate upper surface layer 110a and the openings O_{110b} are formed in the package substrate lower surface layer 110b, the package substrate upper surface layer 110a (upper solder resist layer) and the package substrate lower surface layer 110b may be cured such as by a thermal cure or ultraviolet (UV) cure.

FIG. 2D illustrates a vertical cross-sectional view of an intermediate structure in which the interposer module 120 may be mounted on the package substrate 110 (e.g., via a flip chip bonding (FCB) process) according to one or more embodiments. As illustrated in FIG. 2D, the C4 bumps 121 of the interposer module 120 may be positioned on the package substrate upper bonding pads 114a of the package substrate 110 and heated in order to bond the C4 bumps 121 to the package substrate upper bonding pads 114a.

FIG. 2E illustrates a vertical cross-sectional view of an intermediate structure in which the package underfill layer 129 may be formed on the package substrate 110 according to one or more embodiments. The package underfill layer 129 may be formed of an epoxy-based polymeric material. As illustrated in FIG. 2E, the package underfill layer 129 may be formed (e.g., injected) under and around the interposer module 120 and the C4 bumps 121 so as to fix the interposer module 120 to the package substrate 110. The package underfill layer 129 may then be cured, for example, in a box oven for a duration of about 60 minutes to 120 minutes at a temperature in a range from 120 °C to 180 °C to provide the package underfill layer 129 with a sufficient stiffness and mechanical strength.

FIG. 2F illustrates a vertical cross-sectional view of an intermediate structure in which the TIM layer 140 may be attached to the upper surface of the interposer module 120 according to one or more embodiments. The TIM layer 140 may include, for example, a gel TIM, graphite TIM, metal TIM, solder TIM and a carbon nanotube TIM. The TIM layer 140 may be attached to the upper surface of the interposer module 120 by applying a thermally conductive adhesive to an upper surface of the interposer module 120 (or to a bottom surface of the TIM layer 140), and then pressing the TIM layer 140 onto the interposer module 120.

FIG. 2G illustrates a vertical cross-sectional view of an intermediate structure in which the adhesive 160 may be applied to the package substrate 110 according to one or more embodiments. The adhesive may include, for example, a silicone adhesive or an epoxy adhesive. The adhesive may be located on the package substrate 110 at a position corresponding to a placement of the stiffener ring 150 and in a quantity sufficient to securely bond the stiffener ring 150 to the package substrate 110.

FIG. 2H illustrates a vertical cross-sectional view of an intermediate structure in which the stiffener ring 150 may be attached to (e.g., mounted on) the package substrate 110 according to one or more embodiments. As noted above, the stiffener ring 150 may be composed of metal, ceramic or plastic. The stiffener ring 150 may be formed, for example, by milling using a computer numerical control (CNC) milling machine, or by molding or stamping.

In FIG. 2H, the package substrate 110 with the interposer module 120 may be placed on a surface and the stiffener ring 150 lowered down over the interposer module 120 and onto the package substrate 110. The stiffener ring 150 may then be aligned with the adhesive 160 (e.g., ring of adhesive material) formed on the package substrate 110. The stiffener ring 150 may then be pressed downward by applying a pressing force down onto an upper surface of the stiffener ring 150 so that the stiffener ring 150 may be securely fixed to the package substrate 110 by the adhesive 160. Alternatively, the stiffener ring 150 may be placed on a surface (e.g., a flat surface), and the interposer module 120 on the package substrate 110 may be inverted and inserted into the stiffener ring 150. A downward force may then be applied to the package substrate lower surface layer 110b of the package substrate 110, in order to bond the package substrate 110 to the stiffener ring 150.

FIG. 2I illustrates a vertical cross-sectional view of an intermediate structure in which the package lid 130 may be attached to the stiffener ring 150 according to one or more embodiments. As illustrated in FIG. 2I, at this point in the method of forming the semiconductor package, the package lid 130 may include the filling hole 131 and the degassing hole 133. The filling plug 132 and the degassing plug 134 may not be included in the package lid 130 at this point.

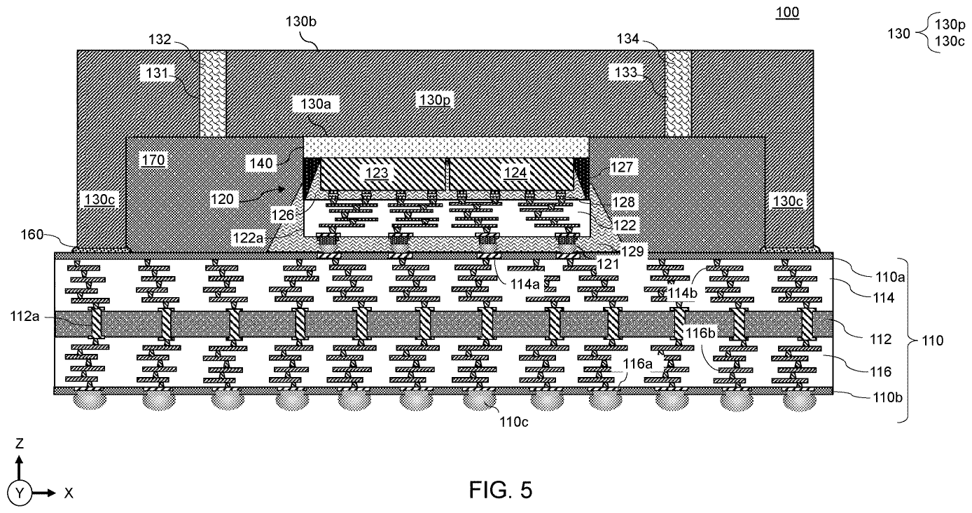

The adhesive 161 may be applied to an upper surface (e.g., an entire upper surface) of the stiffener ring 150. Alternatively, the adhesive 161 may be applied to the bottom surface 130a of the package lid 130 at a location corresponding to a location of the stiffener ring 150. The package lid 130 may then be aligned with the stiffener ring 150 and lowered onto the stiffener ring 150 and the TIM layer 140. The package lid 130 may then be clamped to the package substrate 110 for a period to allow the adhesive 161 and the adhesive 160 to cure and form a secure bond between the package substrate 110, the stiffener ring 150 and the package lid 130. The clamping of the package lid 130 to the package substrate 110 may be performed, for example, by using a heat clamp module. The heat clamp module may apply a uniform force across the upper surface of the package lid 130. In some embodiments as illustrated and described in more detail below with reference to FIG. 5, the stiffener ring 150 may be integrally formed with the package lid 130 in a single structure.

FIG. 2J illustrates a vertical cross-sectional view of an intermediate structure in which the TIM layer protection structure 170 may be added to the semiconductor package 100 according to one or more embodiments. In at least one embodiment, a material (e.g., curable material, liquid material) for forming the TIM layer protection structure 170 may be added to the semiconductor package through the filling hole 131. In particular, the material may be injected (e.g., manually injected) into the semiconductor package 100 so as to fill the volume (e.g., air gap) around the interposer module 120 and constrained by the stiffener ring 150 and package lid 130. Concurrently with the injecting of the material, a gas (e.g., air, nitrogen, etc.) may exit the semiconductor package 100 through the degassing hole 133 in the package lid 130.

In at least one embodiment, the material of the TIM layer protection structure 170 may be injected into the filling hole 131 until the material of the TIM layer protection structure 170 reaches the degassing hole 133. That is, the injecting of the material may be ceased when the material of the TIM layer protection structure 170 reaches the degassing hole 133. In at least one embodiment, the injecting of the material may cease when an uppermost surface of the TIM layer protection structure 170 is substantially coplanar with the bottom surface 130a, a bottom end of the filling hole 131 and a bottom end of the degassing hole 133. In at least one embodiment, the injecting of the material may cease when the TIM layer protection structure 170 fills the entire volume between the interposer module 120 and stiffener ring 150.

FIG. 2K illustrates a plan view of an intermediate structure including the TIM layer protection structure 170 on the package substrate 110 according to one or more embodiments. The package lid 130 has been omitted from FIG. 2K for ease of explanation. A location of the filling hole 131 and a location of the degassing hole 133 are indicated by dashed lines in FIG. 2K.

The directional arrows in FIG. 2K illustrate a direction of flow of the material of the TIM layer protection structure 170 as it is being injected into the filling hole 131. As further illustrated, the material may initially spread out locally around a perimeter of the filling hole 131. The material may spread along the package substrate upper surface layer 110a toward the interposer module 120. A first portion of the material may be caused by the interposer module 120 to initially flow around the interposer module 120 in the x-direction. A second portion of the material may be caused by the interposer module 120 to initially flow around the interposer module 120 in the y-direction. A flow rate of the first portion and a flow rate of the second portion may be substantially the same. The first portion and the second portion may arrive at the degassing hole 133 at substantially the same time.

In at least one embodiment, a filling of the material of the TIM layer protection structure 170 may be automated. In particular, various aspects of the filling process may be computer-controlled by a control system (e.g., electronic control system; central processing unit (CPU)). In at least one embodiment, a beginning of the injecting of the material, a flow rate of the injecting of the material, and a stopping of the injecting of the material may be controlled by the control system.

In at least one embodiment, a vacuum line may be connected to the degassing hole 133 so that a vacuum may be pulled on the volume around the interposer module 120. An imaging device (e.g., camera) may be connected to a portion the vacuum line inserted into the degassing hole 133. The vacuum line and imaging device may also be controlled by the control system. The imaging device may detect a level of the material of the TIM layer protection structure 170. An output of the imaging device may be transmitted (e.g., by wired or wireless signal) to the control system. The control system may cause the injecting of the material to stop and a vacuum in the vacuum line to stop when the output of the imaging device indicates that the material has reached a particular level within the semiconductor package 100 (e.g., when the material has reached the degassing hole 133).

Alternatively, the control system may be programmed to inject a predetermined volume of the material based on various input parameters. The input parameters may include, for example, a volume of the space around the interposer module 120, a size of the interposer module 120, a size of the package lid 130, a size of the stiffener ring 150, etc.

In at least one embodiment, the material for forming the TIM layer protection structure 170 (e.g., an epoxy-based polymeric material) may include a capillary material (e.g., capillary underfill type material). The material may have a low viscosity. In particular, the viscosity of the material may be less than a viscosity of the material of the package underfill layer 129. In at least one embodiment, the viscosity may be less than about 5,000 cP at 10 rpm. In at least one embodiment, the material may include a low-viscosity suspension of thermally conductive material (e.g., metal, metal oxide) in prepolymer. The low viscosity may help to facilitate transport of the material around the interposer module 120 and throughout the space around the interposer module 120. The low viscosity may also help to avoid the formation of voids in the TIM layer protection structure 170. In at least one embodiment, the TIM layer protection structure 170 may be substantially free of voids.

During the process of adding the material of the TIM layer protection structure 170, the material may contact and flow over a surface of the package substrate upper surface layer 110a (e.g., solder resist layer). The surface of the package substrate upper surface layer 110a may have a low surface roughness. In particular, the surface roughness of the package substrate upper surface layer 110a may be less than a surface roughness of the bottom surface 130a of the package lid 130. In at least one embodiment, a surface roughness (arithmetical mean roughness (Ra)) of the package substrate upper surface layer 110 a may be less than 1.0 nm (Ra<1.0 nm). The low surface roughness may help to facilitate flow (transport) of the material in the space around the interposer module 120. A roughness value may include, for example, arithmetical mean roughness (Ra), ten-point mean roughness (Rz), and Rq is the rms root-mean-square (rms) value of the departures of the profile from the mean line, and/or maximum height or depth (Rmax). However, other measures of roughness may be within the scope of disclosure (e.g., mean spacing of profile irregularities (Sm), mean spacing of local peaks of the profile(S), and profile bearing length ratio (tp)).

FIG. 2L illustrates a vertical cross-sectional view of an intermediate structure including the filling plug 132 and the degassing plug 134 according to one or more embodiments. After the material for forming the TIM layer protection structure 170 has been added (e.g., filled the space), the filling plug 132 may be added to (e.g., injected into, inserted into) the filling hole 131. The degassing plug 134 may also be added to (e.g., injected into, inserted into) the degassing hole 133 in the package lid 130. The filling plug 132 and the degassing plug 134 may include the same material as the material of the TIM layer protection structure 170. In at least one embodiment, the filling plug 132 may be formed in the filling hole 131 by injecting a plug material (epoxy-based polymeric material) into the filling hole 131. The degassing plug 134 may be formed in the degassing hole 133 by injecting a plug material (epoxy-based polymeric material) into the degassing hole 133. In at least one embodiment, the filling plug 132 and degassing plug 134 may be formed concurrently with the forming of the TIM layer protection structure 170.

In an alternative embodiment, the material of the filling plug 132 may be different than the material of the degassing plug 134. For example, a material of one of the filling plug 132 and the degassing plug 134 may include a silicone based material, and a material of the other one of the filling plug 132 and the degassing plug 134 may include an epoxy-based polymeric material. In another alternative embodiment, the material of the filling plug 132 and/or the degassing plug 134 may be different than the material of the TIM layer protection structure 170.

FIG. 2M illustrates a vertical cross-sectional view of an intermediate structure in which a plurality of solder balls 110c may be formed on the package substrate 110 according to one or more embodiments. The plurality of solder balls 110c may be formed on the lower bonding pads 116a through the openings in the package substrate lower surface layer 110b. The solder balls 110c may be formed, for example, by an electroplating process. The solder balls 110c may be formed, for example, so as to be located under the stiffener ring 150 and under the interposer module 120. The plurality of solder balls 110c may constitute a ball-grid array (BGA) that may allow the semiconductor package 100 to be securely mounted (e.g., by surface mount technology (SMT)) on a substrate such as a printed circuit board and electrically coupled to the substrate. Formation of the solder balls 110c may complete the formation of the semiconductor package 100.

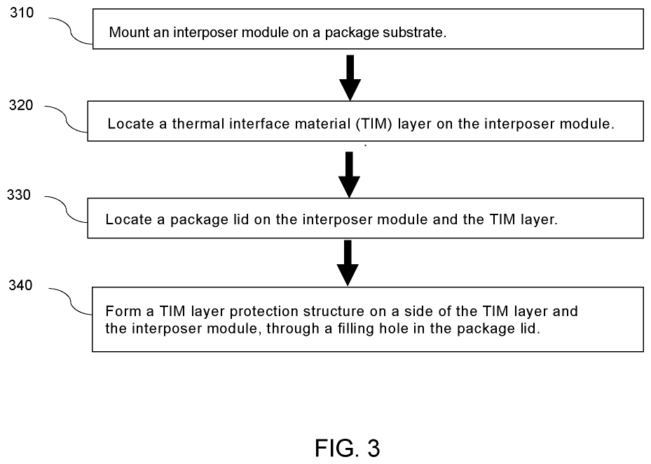

FIG. 3 is a flow chart illustrating a method of forming a semiconductor package according to one or more embodiments. Step 310 includes mounting an interposer module on a package substrate. Step 320 includes locating a thermal interface material (TIM) layer on the interposer module. Step 330 includes locating a package lid on the interposer module and the TIM layer. Step 340 includes forming a TIM layer protection structure on a side of the TIM layer and the interposer module, through a filling hole in the package lid.

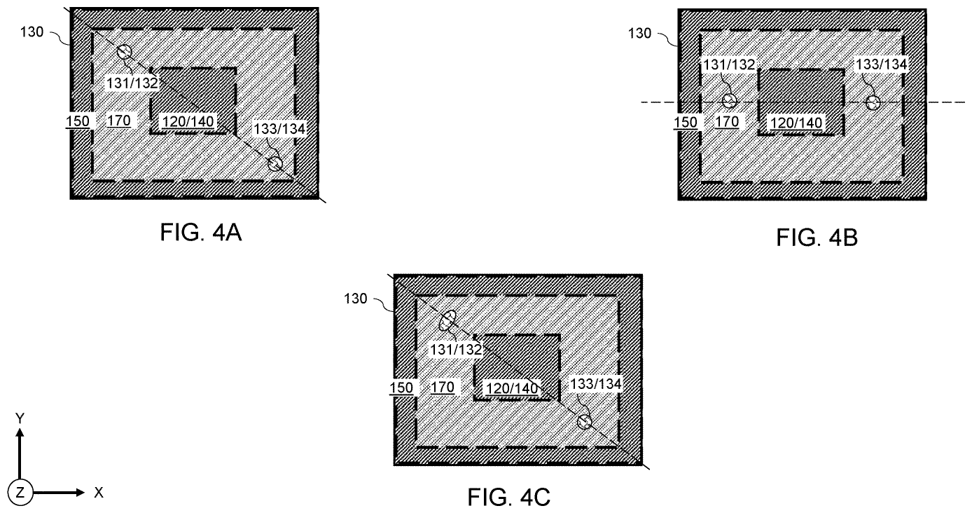

FIGS. 4A-4D illustrate plan views of alternative designs of the package lid 130 according to one or more embodiments. In particular, FIG. 4A illustrates a plan view of a first alternative design of the package lid 130 according to one or more embodiments. In the first alternative design, a distance between the degassing hole 133 and an adjacent corner of the stiffener ring 150 may be less than a distance between the filling hole 131 and an adjacent corner of the stiffener ring 150. This design may help to allow the space between the interposer module 120 and stiffener ring 150 to fill up with more material of the TIM layer protection structure 170 before the material reaches the degassing hole 133.

FIG. 4B illustrates a plan view of a second alternative design of the package lid 130 according to one or more embodiments. In the second alternative design, the filling hole 131 and the degassing hole 133 may be located on opposing sides of the interposer module 120 (and TIM layer 140) in the x-direction. The x-direction may include a longitudinal direction of the package lid 130. In at least one embodiment, the filling hole 131 and the degassing hole 133 may be substantially aligned with a central region of the interposer module 120 (and TIM layer 140).

FIG. 4C illustrates a plan view of a third alternative design of the package lid 130 according to one or more embodiments. In the third alternative design, the filling hole 131 and filling plug 132 may have an oval or elliptical cross-sectional shape. The longitudinal direction of the filling hole 131 and filling plug 132 may be substantially perpendicular to the diagonal line that intersects the opposing corners of the package lid 130. The degassing hole 133 (and degassing plug 134) may have a circular cross-sectional shape.

FIG. 5 illustrates a vertical cross-sectional view of a fourth alternative design of the package lid 130 according to one or more embodiments. As illustrated in FIG. 5, the two-piece unit of the package lid 130 and stiffener ring 150 in the original design in FIG. 1A, may be replaced by a one-piece package lid 130 having an outer foot 130c in lieu of the stiffener ring 150. In particular, the package lid 130 (e.g., one-piece package lid 130) of the fourth alternative design may include a plate portion 130p and the outer foot 130c extending from the plate portion 130p. The outer foot 130c may be integrally formed as a unit with the plate portion 130p (e.g., by CNC processing) and may project perpendicularly from the plate portion 130p around the periphery of the plate portion 130p.

As illustrated in FIG. 5, the filling hole 131 and the degassing hole 133 may be located inside (e.g., in the x-direction) outer foot 130c. Thus, the TIM layer protection structure 170 may be formed in the space bounded by the outer foot 130c, plate portion 130p, package substrate 110 and interposer module 120 (and the TIM layer 140). The fourth alternative design may eliminate a step of bonding the package lid 130 to the stiffener ring 150 and may thereby require less processing time than with the original design of the package lid 130 in FIG. 1A.

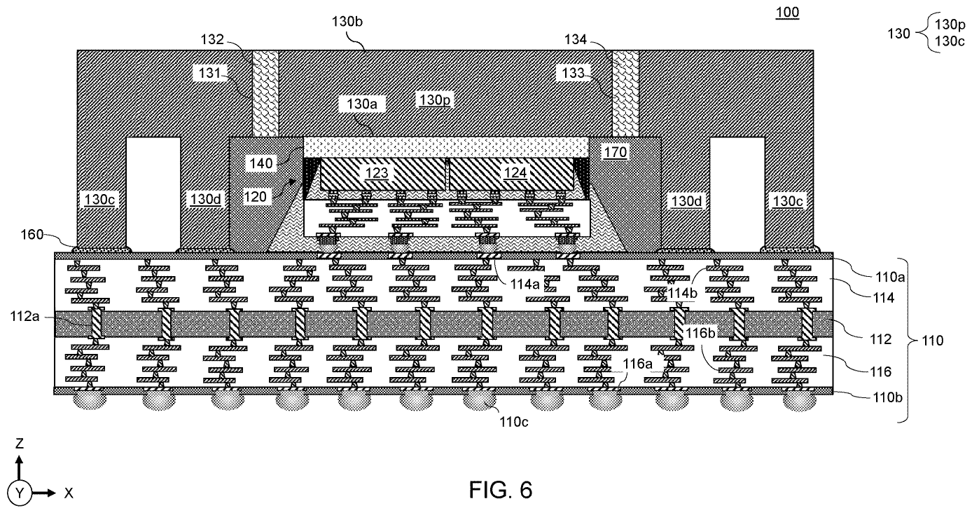

FIG. 6 illustrates a vertical cross-sectional view of a fifth alternative design of the package lid 130 according to one or more embodiments. As illustrated in FIG. 6, the package lid 130 in the fifth alternative design may be similar to the fourth alternative design, but may additionally include an inner foot 130d. In particular, the package lid 130 of the fifth alternative design may include the plate portion 130p and the outer foot 130c integrally formed as a unit with the plate portion 130p. The outer foot 130c may project perpendicularly from the plate portion 130p around the periphery of the plate portion 130p.

The package lid 130 in the fifth alternative design may also include the inner foot 130d that is formed inside the outer foot 130c. The inner foot 130d may project substantially perpendicular from the plate portion 130p. The inner foot 130d may have the same length or different length in the z-direction as the outer foot 130c. The inner foot 130d may also be connected to the package substrate 110 by the adhesive 160.

As illustrated in FIG. 6, the filling hole 131 and the degassing hole 133 may be located inside (e.g., in the x-direction) inner foot 130d. Thus, the TIM layer protection structure 170 may be formed in the volume bounded by the inner foot 130d, plate portion 130p, package substrate 110 and interposer module 120 (and the TIM layer 140). As a result, the fifth alternative design may require less material to fill the volume around the interposer module 120, and less time may be required to fill the volume, as compared to the original design of the package lid 130 in FIG. 1A.

Referring to FIGS. 1A-6, a semiconductor package 100 may include an interposer module 120 on a package substrate 110, a thermal interface material (TIM) layer 140 on the interposer module 120, a TIM layer protection structure 170 on a side surface of the TIM layer 140 and a side surface of the interposer module 120, and a package lid 130 on the interposer module 120, the TIM layer 140 and the TIM layer protection structure 170. A ratio of a thickness of the TIM layer protection structure 170 to a thickness of the interposer module 120 may be in a range between 1.0 and 3.0. The package lid 130 may have a package lid length L₁₃₀ in a first horizontal direction and the TIM layer protection structure 170 may have a TIM layer protection structure length L₁₇₀ in the first direction, and a ratio R1 of the TIM layer protection structure length L₁₇₀ to the package lid length L₁₃₀ may be in a range between 0.3 and 1.0. The package lid 130 may have a package lid width W₁₃₀ in a second horizontal direction perpendicular to the first horizontal direction and the TIM layer protection structure 170 may have a TIM layer protection structure width W₁₇₀ in the second direction, and a ratio R2 of the TIM layer protection structure width W₁₇₀ to the package lid width W₁₃₀ may be in a range between 0.3 and 1.0. The TIM layer protection structure 170 may have a coefficient of thermal expansion in a range between 3 ppm/°C and 20 ppm/°C. The TIM layer protection structure 170 may have a thermal conductivity of greater than 1 W/m·K. The package lid 130 may contact an upper surface of the TIM layer 140 and an upper surface of the TIM layer protection structure 170. The TIM layer protection structure 170 may be formed around a periphery of the TIM layer 140. The TIM layer protection structure 170 may extend across an interface between the TIM layer 140 and a molding material layer 127 of the interposer module 120. The semiconductor package 100 may further include a stiffener ring 150 attached to the package substrate 110 around the interposer module 120, wherein the TIM layer protection structure 170 may be formed in a volume bounded by the stiffener ring 150 and the interposer module 120. The TIM layer protection structure 170 may be bonded to the stiffener ring 150 and may extend continuously from the stiffener ring 150 to the interposer module 120. The TIM layer protection structure 170 may be bonded to the package lid 130 and the package substrate 110 and may extend continuously from the package lid 130 to the package substrate 110. The package lid 130 may include a filling plug 132 over the TIM layer protection structure 170, and a degassing plug 134 over the TIM layer protection structure 170. The package lid 130 may include a plate portion 130p and a foot 130c, 130d extending from the plate portion 130p and contacting the package substrate 110 around a periphery of the interposer module 120, and the TIM layer protection structure 170 may be formed in a space between the foot 130c, 130d and the interposer module 120.

Referring again to FIGS. 1A-6, a method of forming a semiconductor package 100 may include mounting an interposer module 120 on a package substrate 110, locating a thermal interface material (TIM) layer on the interposer module 120, locating a package lid 130 on the interposer module 120 and the TIM layer 140, and forming a TIM layer protection structure 170 on a side surface of the TIM layer 140 and a side surface of the interposer module 120, through a filling hole 131 in the package lid 130. The forming of the TIM layer protection structure 170 may include degassing the space between the stiffener ring 150 and the interposer module 120 through a degassing hole 133 in the package lid 130. The method may further include, plugging a filling hole 131 in the package lid 130 and plugging the degassing hole 133 in the package lid 130. The forming of the TIM layer protection structure 170 may include injecting a TIM layer protection structure material into the filling hole 131 until the TIM layer protection structure material reaches the degassing hole 133. The forming of the TIM layer protection structure 170 may include injecting the TIM layer protection structure material into the filling hole 131 so that an upper surface of the TIM layer protection structure material contacts a bottom surface of the package lid 130 around a periphery of the TIM layer 140.

Referring again to FIGS. 1A-6, a semiconductor package 100 may include an interposer module 120 on a package substrate 110, a thermal interface material (TIM) layer on the interposer module 120, a TIM layer protection structure 170 on the package substrate and around the interposer module and the TIM layer, wherein the TIM layer protection structure 170 may have a coefficient of thermal expansion in a range between 3 ppm/°C and 20 ppm/°C and a thermal conductivity of greater than 1 W/m·K, a stiffener ring 150 attached to the package substrate 110 around the interposer module 120, wherein the TIM layer protection structure 170 may be formed in a volume bounded by the stiffener ring 150 and the interposer module 120, and a package lid 130 on the stiffener ring 150, the interposer module 120, the TIM layer 140 and the TIM layer protection structure 170, wherein the package lid 130 may contact an upper surface of the TIM layer 140 and an upper surface of the TIM layer protection structure 170. The package lid 130 may include a filling hole 131 over the TIM layer protection structure 170 and having a diameter in a range from 3 mm to 10 mm, a filling plug 132 for plugging the filling hole 131, a degassing hole 133 over the TIM layer protection structure 170 and having a diameter in a range from 3 mm to 10 mm, and a degassing plug 134 for plugging the degassing hole 133, and wherein the filling hole 131 may be located on a side of the interposer module 120 that may be opposite the degassing hole 133.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
an interposer module over a package substrate;
a thermal interface material (TIM) layer over the interposer module;
a TIM layer protection structure on a side surface of the TIM layer and a side surface of the interposer module; and
a package lid on the interposer module, the TIM layer and the TIM layer protection structure.

2. The semiconductor package of claim 1, wherein a ratio of a thickness of the TIM layer protection structure to a thickness of the interposer module is in a range between 1.0 and 3.0.

3. The semiconductor package of claim 1, wherein the package lid has a package lid length in a first horizontal direction and the TIM layer protection structure has a TIM layer protection structure length in the first horizontal direction, and a ratio of the TIM layer protection structure length to the package lid length is in a range between 0.3 and 1.0.

4. The semiconductor package of claim 3, wherein the package lid has a package lid width in a second horizontal direction perpendicular to the first horizontal direction and the TIM layer protection structure has a TIM layer protection structure width in the second horizontal direction, and a ratio of the TIM layer protection structure width to the package lid width is in a range between 0.3 and 1.0.

5. The semiconductor package of claim 1, wherein the TIM layer protection structure has a coefficient of thermal expansion in a range between 3 ppm/°C and 20 ppm/°C.

6. The semiconductor package of claim 1, wherein the TIM layer protection structure has a thermal conductivity of greater than 1 W/m·K.

7. The semiconductor package of claim 1, wherein the package lid contacts an upper surface of the TIM layer and an upper surface of the TIM layer protection structure.

8. The semiconductor package of claim 1, wherein the TIM layer protection structure is formed around a periphery of the TIM layer.

9. The semiconductor package of claim 1, wherein the TIM layer protection structure extends across an interface between the TIM layer and a molding material layer of the interposer module.

10. The semiconductor package of claim 1, further comprising:
a stiffener ring adhered to the package substrate and located around the interposer module, wherein the TIM layer protection structure is formed in a volume bounded by the stiffener ring and the interposer module.

11. The semiconductor package of claim 10, wherein the TIM layer protection structure is bonded to the stiffener ring and extends continuously from the stiffener ring to the interposer module.

12. The semiconductor package of claim 10, wherein the TIM layer protection structure is bonded to the package lid and the package substrate and extends continuously from the package lid to the package substrate.

13. The semiconductor package of claim 10, wherein the package lid includes a filling plug over the TIM layer protection structure, and a degassing plug over the TIM layer protection structure.

14. The semiconductor package of claim 1, wherein the package lid comprises a plate portion and a foot extending from the plate portion and contacting the package substrate around a periphery of the interposer module, and the TIM layer protection structure is formed in a volume between the foot and the interposer module.

15. A semiconductor package, comprising:
an interposer module on a package substrate, the interposer module comprising a plurality of semiconductor dies;
a thermal interface material (TIM) layer on the interposer module;
a TIM layer protection structure on the package substrate and around the interposer module and the TIM layer, wherein the TIM layer protection structure has a coefficient of thermal expansion in a range between 3 ppm/°C and 20 ppm/°C and a thermal conductivity of greater than 1 W/m·K;
a stiffener ring attached to the package substrate and located around the interposer module, wherein the TIM layer protection structure is formed in a volume bounded by the stiffener ring and the interposer module; and
a singular package lid on the stiffener ring, the interposer module, the TIM layer and the TIM layer protection structure, wherein the singular package lid covers the interposer module and contacts an upper surface of the TIM layer and an upper surface of the TIM layer protection structure, wherein the singular package lid comprises:
a filling hole over the TIM layer protection structure and having a diameter in a range from 3 mm to 10 mm;
a filling plug for plugging the filling hole, wherein the filling plug comprises a polymeric material;
a degassing hole over the TIM layer protection structure and having a diameter in a range from 3 mm to 10 mm; and
a degassing plug for plugging the degassing hole, wherein the degassing plug comprises a polymeric material,
wherein the filling hole is located on a side of the interposer module that is opposite the degassing hole.

16. The semiconductor package of claim 15, wherein the filling hole and the degassing hole are substantially aligned with opposing corners of the singular package lid.

17. The semiconductor package of claim 15, wherein the filling hole and the degassing hole are substantially aligned with opposing corners of the interposer module.

18. A semiconductor package, comprising:
an interposer module on a package substrate, the interposer module comprising a first semiconductor die and a second semiconductor die mounted on an interposer dielectric layer;
a thermal interface material (TIM) layer on the interposer module;
a stiffener ring attached to the package substrate around the interposer module;
a singular package lid on the stiffener ring and on the TIM layer, wherein the singular package lid covers the interposer module; and
a TIM layer protection structure in a space between the stiffener ring and the interposer module, wherein the TIM layer protection structure contacts a side surface of the TIM layer and a side surface of the interposer module.

19. The semiconductor package of claim 18, wherein the TIM layer protection structure includes a TIM layer protection structure interface portion that contacts a side surface of the TIM layer and a side surface of a molding material layer of the interposer module at an interface between the TIM layer and the molding material layer.

20. The semiconductor package of claim 18, wherein the singular package lid includes a filling hole and a degassing hole, and further comprising a filling plug plugging the filling hole and a degassing plug plugging the degassing hole, wherein the filling plug and the degassing plug comprise a polymeric material.
